(19) United States
(12) Patent Application Publication
(10) Pub. No.: US 2023/0387375 A1
(43) Pub. Date: Nov. 30, 2023

(54) METHOD OF MANUFACTURING ELECTRONIC DEVICE

(71) Applicant: Innolux Corporation, Miao-Li County (TW)

(72) Inventors: Jia-Yuan Chen, Miao-Li County (TW); Tsung-Han Tsai, Miao-Li County (TW); Kuan-Feng Lee, Miao-Li County (TW)

(73) Assignee: Innolux Corporation, Miao-Li County (TW)

(21) Appl. No.: 18/359,891

(22) Filed: Jul. 27, 2023

Related U.S. Application Data
(63) Continuation of application No. 17/070,929, filed on Oct. 15, 2020.

(51) Int. Cl. H01L 33/62; H01L 27/12; H01L 25/075; H01L 25/16

(52) U.S. Cl. CPC H01L 33/62; H01L 27/1214; H01L 25/0753; H01L 25/167; H01L 2933/0066; H01L 27/124

(57) ABSTRACT

A method of manufacturing an electronic device includes the following steps. A substrate is provided, and the substrate has a first surface, a second surface opposite to the first surface and a side surface between the first surface and the second surface. A first circuit is formed on the first surface. The first circuit includes a transistor, a plurality of pads which comprises a first bonding pad, a second bonding pad, a first conductive pad and a first passivation layer. The first passivation layer is disposed on the transistor. The first bonding pad, the second bonding pad and the first conductive pad are respectively disposed on the first passivation layer. A first protection layer is formed on one of the first surface and the second surface. A first cutting lane is formed on the substrate.

### CROSS-REFERENCE TO RELATED APPLICATION

This application is a continuation application of and claims the priority benefit of a prior application Ser. No. 17/070,929, filed on Oct. 15, 2020. The entirety of the above-mentioned patent application is hereby incorporated by reference herein and made a part of this specification.

### BACKGROUND

### Technical Field

The disclosure relates to a method of manufacturing an electronic device, and more particularly to a method of manufacturing an electronic device, which can improve yield or increase process convenience.

### Description of Related Art

Electronic devices are widely used today. With the rapid development of electronic products, the requirements for the display quality of the electronic devices are getting higher and higher.

### SUMMARY

The disclosure is directed to a method of manufacturing an electronic device, which can improve yield or increase process convenience.

According to an embodiment of the disclosure, a method of manufacturing an electronic device includes the following steps. A substrate is provided, and the substrate has a first surface, a second surface opposite to the first surface and a side surface between the first surface and the second surface. A first circuit is formed on the first surface. The first circuit includes a transistor,, a plurality of pads which comprises a first bonding pad, a second bonding pad, a first conductive pad and a first passivation layer. The first passivation layer is disposed on the transistor. The first bonding pad, the second bonding pad and the first conductive pad are respectively disposed on the first passivation layer. A first protection layer is formed on one of the first surface and the second surface. A first cutting lane is formed on the substrate.

To make the aforementioned more comprehensible, several embodiments accompanied with drawings are described in detail as follows.

### BRIEF DESCRIPTION OF THE DRAWINGS

The accompanying drawings are included to provide a further understanding of the disclosure, and are incorporated in and constitute a part of the specification. The drawings illustrate exemplary embodiments of the disclosure and, together with the description, serve to explain the principles of the disclosure.

FIG. 1 is a flowchart of a method of manufacturing an electronic device according to an embodiment of the disclosure.

FIGS. 2A, 3A, 4A, 5A, 6A, 7A, 8A, and 9A are schematic top views of a method of manufacturing an electronic device according to an embodiment of the disclosure.

FIGS. 2B, 3B, 4B, 5B, 6B, 7B, 8B, and 9B are schematic cross-sectional views of a method of manufacturing an electronic device of FIG. 2A to FIG. 9A along the section line A-A′.

FIG. 10 is a schematic cross-sectional view of a structure according to another embodiment of the disclosure.

FIG. 11 is a schematic top view of a structure according to another embodiment of the disclosure.

FIG. 12 is a schematic top view of a structure according to another embodiment of the disclosure.

FIG. 13 is a schematic cross-sectional view of a structure according to another embodiment of the disclosure.

FIG. 14 is a schematic cross-sectional view of a structure according to another embodiment of the disclosure.

FIG. 15 is a schematic top view of a structure according to another embodiment of the disclosure.

FIG. 16 is a schematic top view of a structure according to another embodiment of the disclosure.

### DESCRIPTION OF THE EMBODIMENTS

The disclosure can be understood by referring to the following detailed description in conjunction with the accompanying drawings. It should be noted that in order to make the reader easy to understand and for the sake of simplicity of the drawings, the multiple drawings in the disclosure only depict a part of the electronic device, and certain elements in the drawings are not drawn according to actual scale. In addition, the number and size of each element in the figure are only for illustration, and are not intended to limit the scope of the present disclosure.

Certain terms are used throughout the description and following claims to refer to particular components. As one skilled in the art will understand, electronic equipment manufacturers may refer to a component by different names. This document does not intend to distinguish between components that differ in name but not function.

In the following description and in the claims, the terms “include”, “comprise” and “have” are used in an open-ended fashion, and thus should be interpreted to mean “include, but not limited to . . . ”. Thus, when the terms “include”, “comprise” and/or “have” are used in the description of the present disclosure, the corresponding features, areas, steps, operations and/or components would be pointed to existence, but not limited to the existence of one or a plurality of the corresponding features, areas, steps, operations and/or components.

It should be understood that when an element or film is referred to as being “on” or “connected to” another element or layer, it can be directly on or directly connected to the other element or layer, or exist an intervening element or layer between the two (indirect case). In contrast, when an element is referred to as being “directly on” or “directly connected to” another element or layer, there are no intervening elements or layers present.

The terms “about”, “approximately”, and “substantially” generally mean a feature value is within a range of 20% of a given value, or within 10%, 5%, 3%, 2%, 1%, or 0.5% of a given value. The quantity given in the specification is an approximate quantity, that is, even without specifying “about”, “approximately”, “substantially”, it still implies the meaning of “about”, “approximately” and “substantially”.

In addition, the phrase “in a range from a first value to a second value” indicates the range includes the first value, the second value, and other values in between.

The electronic device of the disclosure may include a display device, an antenna device (such as liquid crystal antenna), a sensing device, a lighting device, a touch device, a curved device, a free shape device, a bendable device, flexible device, tiled device or a combination thereof, but is not limited thereto. The electronic device may include light-emitting diode (LED), liquid crystal, fluorescence, phosphor, other suitable materials or a combination thereof, but is not limited thereto. The light emitting diode may include organic light emitting diode (OLED), inorganic light emitting diode, mini LED, micro LED or quantum dot (QD) light emitting diode (QLED, QDLED), other suitable types of LEDs or any combination of the above, but is not limited thereto. The display device may also include, for example, a tiled display device, but is not limited thereto. The antenna device may be, for example, a liquid crystal antenna, but is not limited thereto. The antenna device may include, for example, a tiled antenna device, but is not limited thereto. It should be noted that the electronic device can be any combination of the above, but is not limited thereto. The electronic device may have peripheral systems such as a driving system, a control system, a light source system, a shelf system, etc., to support a display device, an antenna device, or a tiled device. Hereinafter, an electronic device will be used to illustrate the content of the disclosure, but the disclosure is not limited thereto.

Although the terms first, second, third etc. can be used to describe various constituent elements, the constituent elements are not limited by the terms. The term is only used to distinguish a single constituent element from other constituent elements in the specification. The same terms may not be used in the claims, but may be replaced by first, second, third, etc. in the order of element declarations in the claims. Therefore, in the following specification, a first constituent element may be a second constituent element in the claims.

In some embodiments of the present disclosure, unless specifically defined otherwise, the terms related to joining and connection, such as “connected” and “interconnected”, may refer to two structures being in direct contact, or may refer to two structures not being in direct contact and other structures are provided between the two structures. Moreover, the terms about joining and connecting may include a case where two structures are movable or two structures are fixed. In addition, the term “coupled” includes any direct and indirect electrical connection means.

It will be understood that when an element or layer is referred to as being “(electrically) connected to” another element or layer, it can be directly (electrically) connected to the other element or layer, or intervening elements or layers may be presented. In contrast, when an element is referred to as being “directly (electrically) connected to” another element or layer, there are no intervening elements or layers presented. In contrast, when an element is referred to as being “disposed on” or “formed on” A element, it may be directly disposed on (or formed on) A element, or may be indirectly disposed on (or formed on) A element through other component. In contrast, when an element is referred to as being “disposed between” A element and B element, it may be directly disposed between A element and B element, or may be indirectly disposed between A element and B element through other component.

It should be noted that the following embodiments can be replaced, recombined, and mixed to complete other embodiments without departing from the spirit of the present disclosure.

Reference will now be made in detail to the exemplary embodiments of the disclosure, examples of which are illustrated in the accompanying drawings. Whenever possible, the same reference numerals are used to represent the same or similar parts in the accompanying drawings and description.

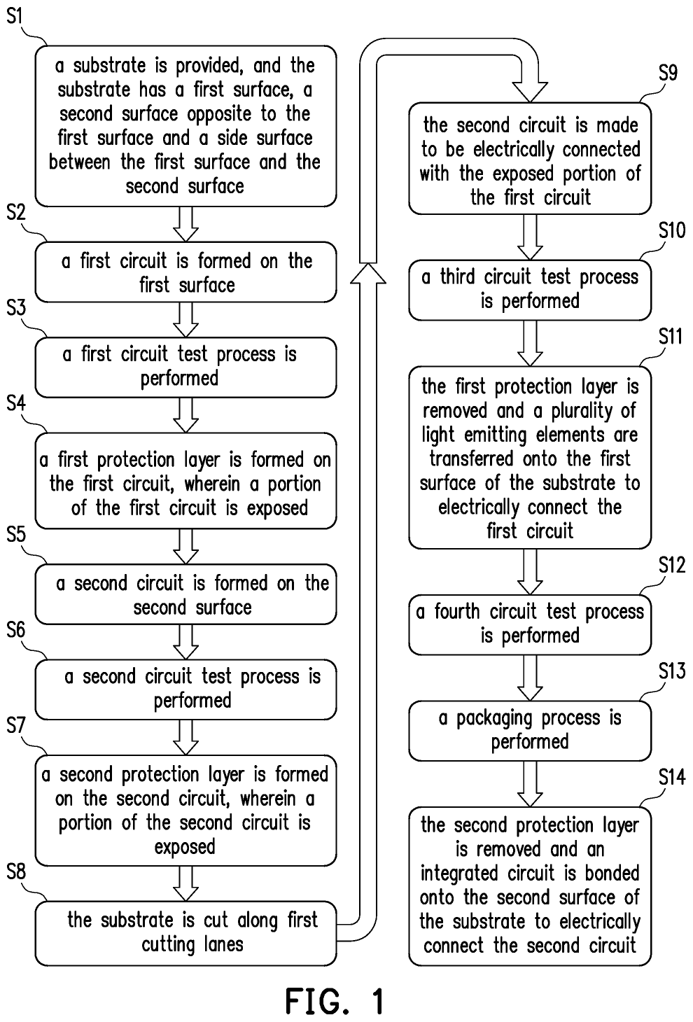

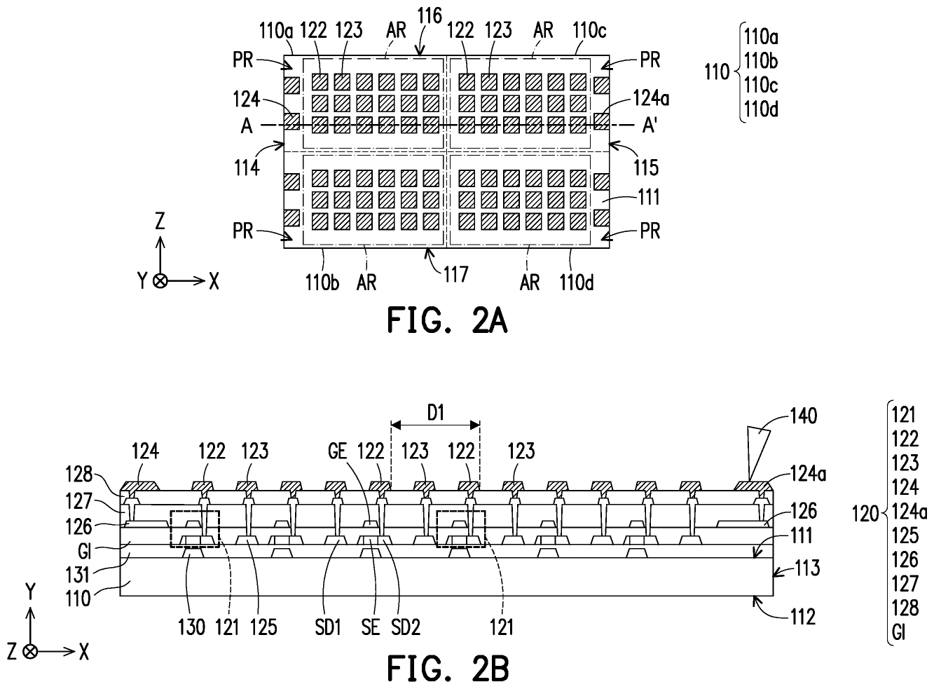

FIG. 1 is a flowchart of a method of manufacturing an electronic device according to an embodiment of the disclosure. FIG. 2A to FIG. 9A are schematic top views of a method of manufacturing an electronic device according to an embodiment of the disclosure. FIG. 2B to FIG. 9B are schematic cross-sectional views of a method of manufacturing an electronic device of FIG. 2A to FIG. 9A along the section line A-A′. For the sake of clarity and easy description of the drawings, FIG. 2A to FIG. 9A omit illustration of several elements.

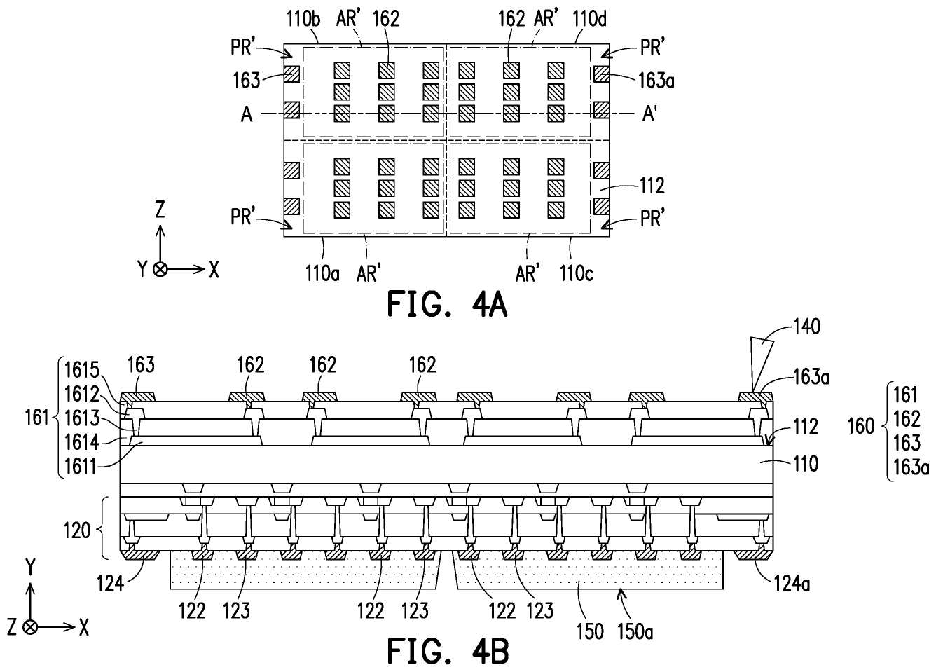

Referring to FIG. 1, FIG. 2A, and FIG. 2B simultaneously, in the method of manufacturing the electronic device in the present embodiment, the steps S1, S2, and S3 can be sequentially performed. In the step S1, a substrate 110 is provided. The substrate 110 has a first surface 111, a second surface 112 opposite to the first surface 111 and a side surface 113 between the first surface 111 and the second surface 112. In the present embodiment, the substrate 110 may include four edges 114, 115, 116, and 117, wherein the edge 114 is opposite to the edge 115 and the edge 116 is opposite to the edge 117. The substrate 110 includes an area enough for a plurality of regions 110a, 110b, 110c, and 110d to manufacture the electronic devices (FIG. 2A schematically shows four regions, but is not limited thereto), and each of the regions 110a, 110b, 110c, and 110d includes an active region AR and a peripheral region PR on the first surface 111, on the other hand, the regions 110a, 110b, 110c, and 110d may respectively include a first region AR′ (shown in FIG. 4A) corresponding to the active region AR and a second region PR′ (shown in FIG. 4A) corresponding to the peripheral regions PR on the second surface. The peripheral regions PR are located corresponding to the edge 114 and the edge 115 of the substrate 110. In the present embodiment, the substrate 110 may include a rigid substrate, a flexible substrate or a combination thereof. For example, a material of the substrate 110 may include glass, quartz, sapphire, ceramics, polycarbonate (PC), polyimide (PI), polyethylene terephthalate (PET), other suitable substrate materials or a combination of the above, but is not limited thereto.

In the present embodiment, a direction X, a direction Y and a direction Z are different from each other. The direction X, the direction Y and the direction Z may be substantially perpendicular to each other. The direction Y may be, for example, a normal direction of the substrate 110, but the disclosure is not limited thereto.

In the step S2, a first circuit 120 is formed on the first surface 111 of the substrate 110. Specifically, in the present embodiment, before forming the first circuit 120, a plurality of light shielding elements 130 and a buffer layer 131 covering the light shielding elements 130 are formed on the first surface 111 of the substrate 110. Next, the first circuit 120 is formed on the buffer layer 131. The first circuit 120 may include layers, electronic elements and conductive lines, such as a plurality of transistors 121, a plurality of first bonding pads 122, a plurality of second bonding pads 123, a plurality of first conductive pads 124 and 124a, a plurality of first signal wires 125, a plurality of second signal wires 126, an insulation layer GI, a first passivation layer 127 and a second passivation layer 128, but is not limited thereto. It should be noted that the plurality of first bonding pads 122 and the plurality of second bonding pads 123 may receive different kinds of signals. In some embodiments, the first circuit 120 may include some other electronic components, such as driver IC and/or sensors. The transistor 121 includes a gate electrode GE, a semiconductor layer SE, a source electrode SD1 and a drain electrode SD2, and a portion of the insulation layer GI as a gate insulation layer, but is not limited thereto. The plurality of first bonding pads 122, the plurality of second bonding pads 123 are respectively disposed in the active regions AR of the substrate 110, and the plurality of first conductive pads 124 and 124a are respectively disposed in the peripheral regions PR of the regions 110a, 110b, 110c, and 110d of the substrate 110. As shown in FIG. 2B, there is a distance D1 between a side (e.g., the right side) of a first bonding pad 122 and a corresponding side (e.g., the right side) of an adjacent first bonding pad 122. It should be noted that in some embodiments, there may be one or more intervening second bonding pads 123 between the two adjacent first bonding pads 122. In the present embodiment, the distance D1 is, for example, the distance measured along the direction X. It should be noted that the first bonding pads 122, the second bonding pads 123, the first conductive pads 124 and 124a, the first signal wires 125, and the second signal wires 126 may respectively be a single-layered structure or a multiple-layered structure, there is no limitation.

More specifically, the transistors 121 are disposed on the buffer layer 131, and the semiconductor layers SE is disposed corresponding to the light shielding element 130. The insulation layer GI is disposed on the buffer layer 131, and is disposed between the gate electrodes GE and the semiconductor layers SE. The first signal wires 125 are disposed on the buffer layer 131 and are covered by the insulation layer GI. The second signal wires 126 and the gate electrode GE are disposed on the insulation layer GI. In the present disclosure, the first signal wires 125 can be used to provide low voltage signals, and the second signal wires 126 can be used to provide test signals, but the present disclosure is not limited thereto. The first passivation layer 127 is disposed on the transistors 121. The first passivation layer 127 is disposed on the insulation layer GI and covers the second signal wires 126 and the gate electrodes GE. The second passivation layer 128 is disposed on the first passivation layer 127. The first bonding pads 122, the second bonding pads 123, the first conductive pads 124 and the first conductive pads 124a are respectively disposed on the first passivation layer 127 and the second passivation layer 128. The first bonding pads 122, the second bonding pads 123, the first conductive pads 124 and the first conductive pads 124a are disposed on the same layer. The first bonding pad 122 is electrically connected to the corresponding transistors 121. The second bonding pad 123 is electrically connected to the corresponding first signal wires 125. The first conductive pad 124 is electrically connected to the corresponding second signal wires 126. In addition, the transistors 121, the first bonding pads 122 and the second bonding pads 123 are disposed in the active regions AR of the regions 110a, 110b, 110c, and 110d. The first conductive pads 124 and the first conductive pads 124a are disposed in the peripheral regions PR of the regions 110a, 110b, 110c, and 110d.

In the step S3, a first circuit test process is performed. Specifically, a predetermined voltage is applied to the first circuit 120 to test whether abnormal circuit issues happen in the first circuit 120. For example, the predetermined voltage is applied to the first conductive pads 124a (or the first conductive pads 124) of the first circuit 120 by contacting probe(s) 140. A test result is obtained to determine whether the open circuit, short circuit, and/or other abnormal circuit issues happen in the first circuit 120.

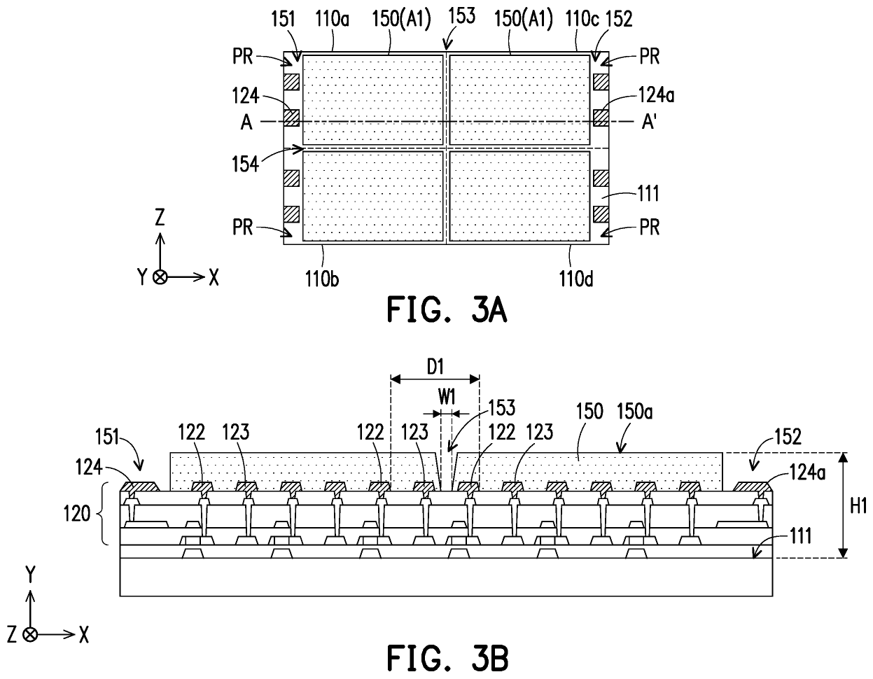

Referring to FIG. 1, FIG. 3A, and FIG. 3B simultaneously, the step S4 is performed. In the step S4, a first protection layer 150 is formed on the first circuit 120, wherein at least a portion (such as first conductive pads 124 and 124a, but is not limited thereto) of the first circuit 120 is exposed. Specifically, in the present embodiment, the first protection layer 150 covers the plurality of transistors 121, the plurality of first bonding pads 122 and the plurality of second bonding pads 123 of the first circuit 120. But the disclosure is not limited thereto. The first protection layer 150 has a top surface 150a away from the first circuit 120. There is a distance H1 between the first surface 111 of the substrate 110 and the top surface 150a of the first protection layer 150. In the present embodiment, the distance H1 is, for example, the maximum distance measured along the direction Y between the first surface 111 of the substrate 110 and the top surface 150a of the first protection layer 150.

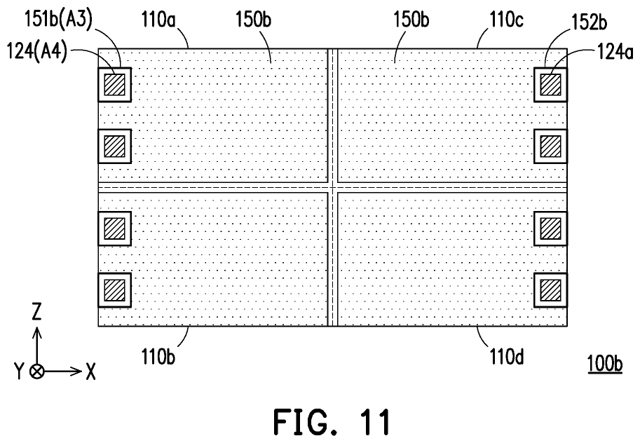

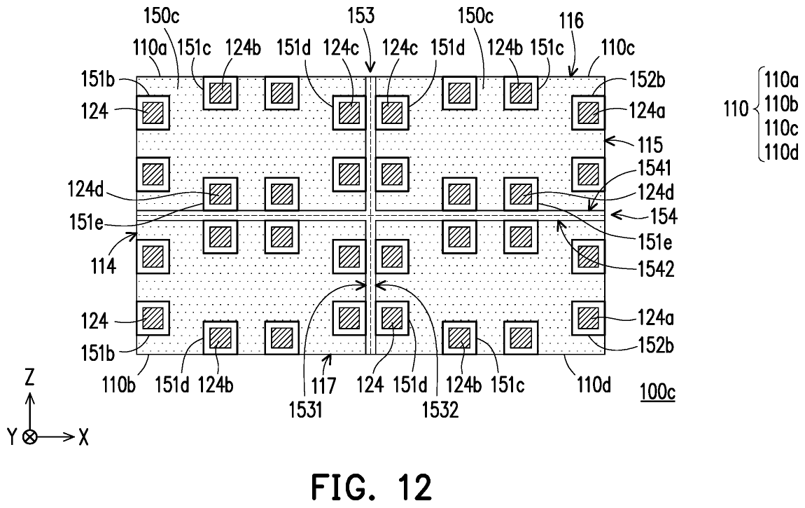

A plurality of first openings 151 and 152 and a plurality of first cutting lanes 153 and 154 are located adjacent to the first protection layer 150. It should be noted that there are only two first openings 151 and 152 and only two first cutting lanes 153 and 154 in FIG. 3A, but the number of first openings and first cutting lanes are not limited thereto. The first opening 151 (or the first opening 152) is located in the peripheral regions PR of the region 110a and the region 110b (and/or the region 110c and the region 110d) to expose at least the plurality of first conductive pads 124 (or the first conductive pads 124a) of the first circuit 120. In the present embodiment, the first opening 151 and the first opening 152 are trenches, but are not limited thereto. In some embodiments, the first openings are via holes, as shown in FIGS. 11 and 12. In the present embodiment, the first opening 151 and the first opening 152 may extend in a direction parallel to the direction Z, the first opening 151 exposes one or more first conductive pads 124, and the first opening 152 exposes one or more first conductive pads 124a Similarly, in some embodiments, the first cutting lane 153 and/or the first cutting lane 154 may expose one or more conductive pads (not shown).

The first cutting lane 154 is parallel to the direction X. The first cutting lane 153 is parallel to the direction Z. The first cutting lane 153 intersects the first cutting lane 154 and may be substantially perpendicular to each other. The first cutting lane 153 is located corresponding to a boundary between the adjacent regions 110a and 110c and a boundary between the adjacent regions 110b and 110d. The first cutting lane 154 is located corresponding to a boundary between the adjacent regions 110a and 110b and a boundary between the adjacent regions 110c and 110d. It should be noted that the boundary between two regions is a predetermined cutting line to separate the two regions. The first cutting lanes 153 and 154 may respectively have a width. In the present embodiment, the first cutting lane 153has a width W1. The distance D1 is greater than the width W1 of the first cutting lane 153. In the present embodiment, the width W1 is, for example, the minimum width of the first cutting lane 153 measured along a direction perpendicular to the extending direction of the first cutting lane 153. The measuring method is also suitable to measure the width of the first cutting lane 154.

In the present embodiment, the first protection layer 150 may be formed, for example, in the following steps: First, a protection material (not shown) is coated on the first surface 111 of the substrate 110, and the protection material may completely or partially cover the first circuit 120 (for example, covers the first bonding pads 122, the second bonding pads 123, the first conductive pads 124 and 124a, but is not limited to thereto); then, a patterning process may be performed on the protection material to form the first protection layer 150 and the first openings land 152 and the first cutting lanes 153 and 154; then, a baking process may be performed on the first protection layer 150 to harden a surface of the first protection layer 150 to have a protection effect.

In some embodiments, the first protection layer 150 may also be formed, for example, in the following steps: First, a patterned first protection layer 150 is transferred on the first surface 111 of the substrate 110, for example, by a screen printing method, and the patterned first protection layer 150 may cover the first bonding pads 122 and the second bonding pads 123, and expose the first conductive pads 124 and 124a and the boundary between the regions 110a, 110b, 110c, and 110d; then, a baking process may be performed on the patterned first protection layer 150 to harden a surface of the patterned first protection layer 150 to have a protection effect. In some embodiments, a material of the patterned first protection layer 150 is a baking type peelable glue, but is not limited thereto. The baking type peelable glue has characteristics of rapid hardening and good printability, and when the baking type peelable glue is heated to form a film, it can resist acid and alkali and can be peeled off by a laser lifting off method or other suitable peeling methods.

In the present embodiment, the first protection layer 150 may be a single-layered or multi-layered structure, and may include, for example, organic materials, inorganic materials, or a combination of the above, but is not limited thereto. The organic material may include, for example, a polymer material such as polyimide resin, epoxy resin, acrylic resin, other suitable materials, or a combination thereof. The inorganic material may include, for example, silicon oxide, silicon nitride, silicon oxynitride, a stacked layer of at least two of the above materials, other suitable materials, or a combination thereof. In addition, when the first protection layer 150 is a multi-layered structure, the outer layer may be denser (e.g., a material of higher density) and the inner layer may be looser (e.g., a material of lower density or a porous material), and the first protection layer can be separated in a subsequent process. In the present embodiment, a thickness of the first protection layer 150 is, for example, 2 μm to 20 μm (2 μm≤thickness≤20 μm), such as 5 μm, 10 μm or 15 μm, but is not limited thereto. In some embodiments, a material of the first protection layer 150 may also include a photoresist material or a loosely structured inorganic material, but not limited thereto.

Referring to FIG. 1, FIG. 4A, and FIG. 4B simultaneously, the steps S5 and S6 are sequentially performed. In the step S5, a second circuit 160 is formed on the second surface 112 of the substrate 110. Specifically, the second circuit 160 may include a redistribution layer 161, a plurality of third bonding pads 162 and a plurality of second conductive pads 163 and 163a, but is not limited thereto. The redistribution layer 161 includes a plurality of first conductive elements 1611, a plurality of second conductive elements 1612, a plurality of conductive vias 1613, a third passivation layer 1614 and a fourth passivation layer 1615. The plurality of third bonding pads 162 are disposed in the first regions AR′ of the substrate 110, and the plurality of second conductive pads 163 and 163a are disposed in the second regions PR′ of the substrate 110. In some embodiments, the second circuit 160 may include some other electronic components, such as driver ICs and/or sensors, but not limited thereto.

More specifically, the plurality of first conductive elements 1611 are disposed on the second surface 112 of the substrate 110. The third passivation layer 1614 is disposed on the second surface 112 of the substrate 110 and covers the first conductive elements 1611. The second conductive elements 1612 are disposed on the third passivation layer 1614. It should be noted that the first conductive elements 1611 may be formed by patterning a layer, and The second conductive elements 1612 may be formed by patterning a layer, but the disclosure is not limited thereto. The fourth passivation layer 1615 is disposed on the third passivation layer 1614 and covers the second conductive elements 1612. The conductive vias 1613 penetrate the third passivation layer 1614 and the first conductive elements 1611 are electrically connected with the corresponding second conductive elements 1612 respectively. The third bonding pads 162 and the second conductive pads 163 and 163a are respectively disposed on the fourth passivation layer 1615 and are respectively electrically connected to the corresponding ones of the second conductive elements 1612. In addition, the third bonding pads 162 are disposed in the first regions AR′ of the regions 110a, 110b, 110c and 110d. The second conductive pads 163 and 163a are disposed in the second regions PR′ of the regions 110a, 110b, 110c and 110d. The plurality of first conductive pads 124 and 124a may overlap the second conductive pads 163 and 163a in the normal direction (e.g. direction Y) of the substrate 110. Specifically, the plurality of first conductive pads 124 and 124a may respectively overlap more than 50% of the area of their corresponding second conductive pads 163 and 163a in a top view, but is not limited thereto. It should be noted that each of the third bonding pads 162 and the second conductive pads 163 and 163a may be a single-layered structure or a multiple-layered structure.

In the step S6, a second circuit test process is performed. Specifically, a predetermined voltage is applied to the second circuit 160 to test whether abnormal circuit issues happen in the second circuit 160. For example, the predetermined voltage is applied to the second conductive pads 163a (or second conductive pads 163) of the second circuit 160 by contacting the probe(s) 140. A test result is obtained to determine whether the open circuit, short circuit, and/or other abnormal circuit issues happen in the second circuit 160.

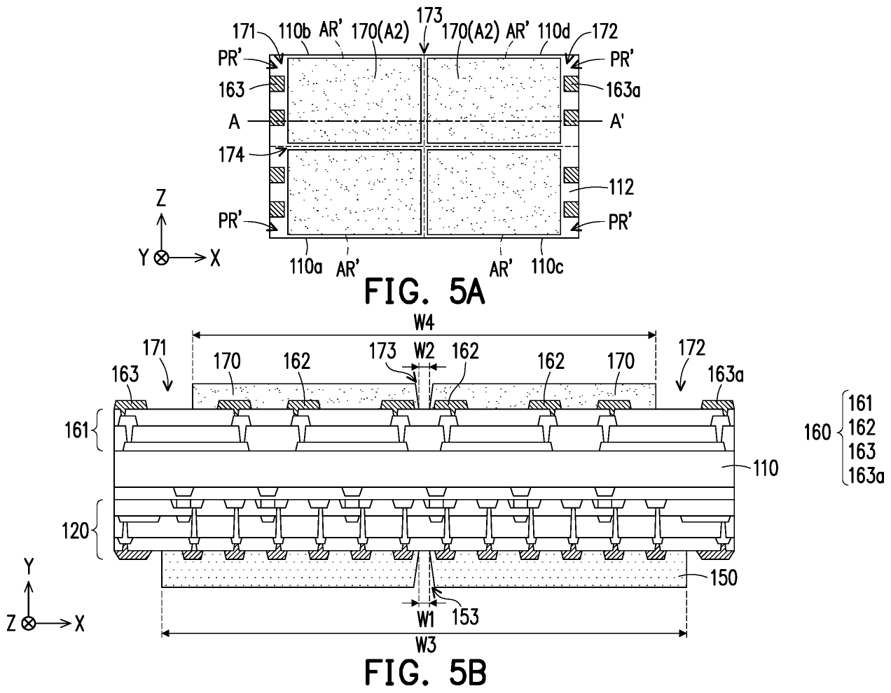

Referring to FIG. 1, FIG. 5A, and FIG. 5B simultaneously, the step S7 is performed. In the step S7, a second protection layer 170 is formed on the second circuit 160, wherein a portion of the second circuit 160 is exposed. Specifically, in the present embodiment, the second protection layer 170 may cover the redistribution layer 161 and the plurality of the third bonding pads 162 of the second circuit 160. In the present embodiment, the formation steps, structure or material of the second protection layer 170 may be the same or similar to the first protection layer 150, so it will not be repeated here.

A plurality of second openings 171 and 172 and a plurality of second cutting lanes 173 and 174 are located adjacent to the second protection layer 170. The second opening 171 (or the second opening 172) is located in the peripheral regions PR of the region 110a and the region 110b (or the region 110c and region 110d) to expose at least the plurality of second conductive pads 163 (or the second conductive pads 163a) of the second circuit 160. In the present embodiment, the second opening 171 and the second opening 172 may be trenches, but are not limited thereto. In the present embodiment, the second opening 171 and the second opening 172 extend in a direction parallel to the direction Z. The second openings 171 exposes the second conductive pads 163 and the second openings 172 exposes the second conductive pads 163a. Similarly, in some embodiments, the second cutting lane 173 and/or the first cutting lane 174 may expose one or more second conductive pads 163. It should be noted that there are only two second openings 171 and 172 and only two second cutting lanes 173 and 174 in FIG. 5A, but the number of the second openings and the second cutting lanes are not limited thereto.

The second cutting lane 174 is parallel to the direction X. The second cutting lane 173 is parallel to the direction Z. The second cutting lane 173 intersects the second cutting lane 174 and may be substantially perpendicular to each other. The second cutting lane 173 is located corresponding to a boundary between the adjacent regions 110a and 110c and a boundary between the adjacent regions 110b and 110d. The second cutting lane 174 is located corresponding to a boundary between the adjacent regions 110a and 110b and a boundary between the adjacent regions 110c and 110d. The second cutting lanes 173 and 174 respectively have a width. In the present embodiment, the width W2 of the second cutting lane 173 is, for example, the minimum width measured along a direction perpendicular to the extending direction of the second cutting lane 173. The measuring method is also suitable to measure the width of the second cutting lane 174.

In the present embodiment, the plurality of first cutting lanes 153 and 154 may respectively overlap the corresponding one of plurality of second cutting lanes 173 and 174 in the normal direction (direction Y) of the substrate. To be more specific, the first cutting lane 153 (and/or the first cutting lane 154) and the second cutting lanes 173 (and/or the second cutting lane 174) may overlap by more than 50% in the normal direction (Y direction) of the substrate 110, but is not limited thereto. The width W1 of the first cutting lane 153 may be different from the width W2 of the second cutting lane 173. In addition, in the present embodiment, an area A1 of the first protection layer 150 may be greater than an area A2 of the second protection layer 170. To be more specific, the area A1 of the first protection layer 150 formed on the first surface of the substrate 110 is greater than the area A2 of the second protection layer 170 formed on the second surface of the substrate 110. A width W3 of the first protection layer 150 may be greater than a width W4 of the second protection layer 170. In the present embodiment, the width W3 is, for example, the maximum width of the first protection layer 150 measured along the direction X. The width W4 is, for example, the maximum width of the second protection layer 170 measured along the direction X.

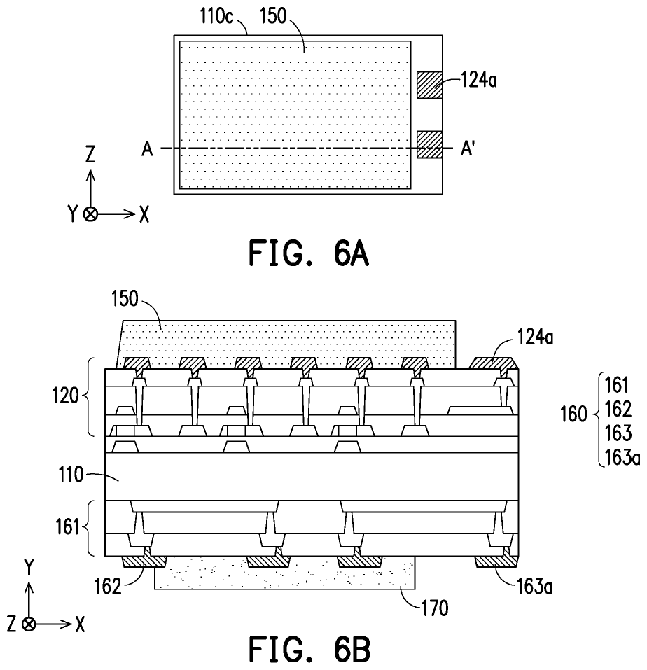

Referring to FIG. 1, FIGS. 5A-6A and FIGS. 5B-6B simultaneously, the step S8 is performed. In the step S8, the substrate 110 is cut along the first cutting lane 153 and the first cutting lane 154 (or the second cutting lanes 173 and the second cutting lanes 174) by a cutting tool, and each of the regions 110a, 110b, 110c, and 110d of the substrate 110 is separated from each other. In the present embodiment, the width W1 of the first cutting lane 153 is greater than a cutting width of the cutting tool. It should be noted that in some embodiments, an additional patterning process may be performed to expose at least one of the second conductive pads 162 which is shown in FIG. 6B.

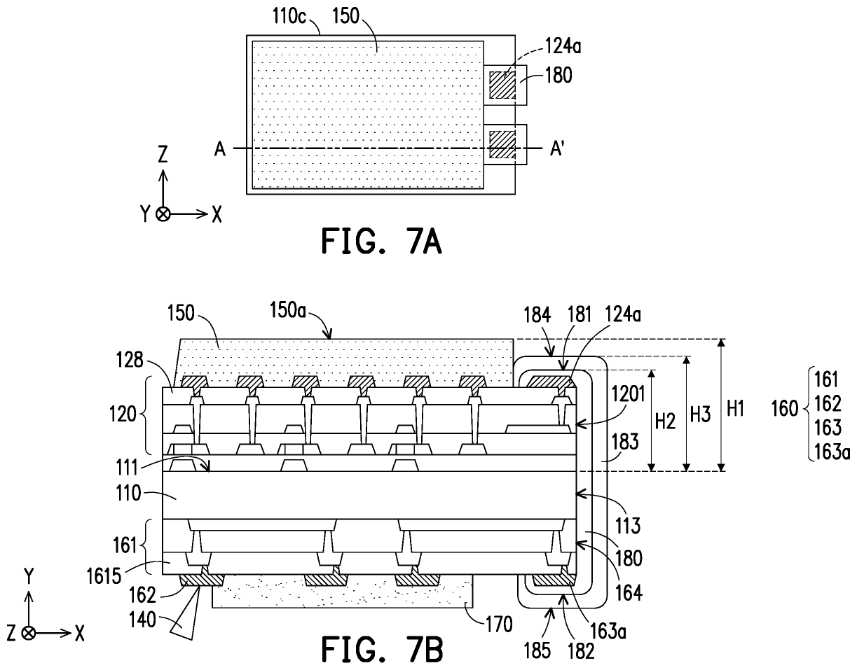

Referring to FIG. 1, FIG. 7A, and FIG. 7B simultaneously, the steps S9 and S10 are performed. In the step 9, the second circuit 160 is made to be electrically connected with the exposed portion of the first circuit 120. For example, in the present embodiment, the second circuit 160 may be electrically connected to the exposed portion of the first circuit 120 through a connection pattern 180, but is not limited thereto. Specifically, in the present embodiment, the connection pattern 180 is at least formed on the side surface 113 of the substrate 110, and the second circuit 160 may be electrically connected with the exposed portion of the first circuit 120 through the connection pattern 180. In other words, the connection pattern 180 may be regarded as a conductive pattern on the side surface 113 of the substrate 110. In some embodiments, the connection pattern 180 may also be disposed on a side surface 1201 of the first circuit 120 and a side surface 164 of the second circuit 160. In some embodiments, the ends of the connection pattern 180 may also be disposed on the first circuit 120 and the second circuit 160 to respectively contact an upper surface of at least one of the first conductive pads 124a of the first circuit 120 and an upper surface of at least one of the second conductive pads 163a of the second circuit 160, thereby protecting the at least one of the first conductive pads 124a and the at least one of the second conductive pads 163a from damage. It should be noted that in some embodiments, the connection pattern 180 may contact only a side portion of the at least one of the first conductive pads 124a (and/or a side portion of the at least one of the second conductive pads 163a) rather than contacting the upper surface of it. In other embodiments, there may be an intervening conductive element between the connection pattern 180 and the at least one of the first conductive pads 124a (or the at least one of the second conductive pads 163a) to form an electrical connection.

In addition, as shown in FIG. 7B, when the connection pattern 180 contacts the upper surface of the at least one of the first conductive pads 124a of the first circuit 120 and the upper surface of the at least one of the second conductive pads 163a of the second circuit 160, the connection pattern 180 has an upper surface 181 farthest from the second circuit 160 and a lower surface 182 farthest from the first circuit 120. To be more specific, the upper surface 181 may be a surface of a portion of the connection pattern 180 that the portion is higher than the second passivation layer 128 along the Y-direction, similarly, and the lower surface 182 may be a surface of another portion of the connection pattern 180 that the another portion is lower than the fourth passivation layer 1615 along the Y-direction. There is a distance H2 between the first surface 111 of the substrate 110 and the topmost point of the connection pattern 180. In the present embodiment, the distance H1 between the first surface 111 of the substrate 110 and the top surface 150a of the first protection layer 150 may be greater than the distance H2. To be more specific, the distance H1 is the maximum distance between the first surface 111 of the substrate 110 and the top surface 150a of the first protection layer 150 measured along the Y-direction, and the distance H2 is the maximum distance between the first surface 111 of the substrate 110 and the topmost point of the connection pattern 180 measured along the Y-direction. Therefore, when the connection pattern 180 is disposed, the first protection layer 150 may be used to protect the connection pattern 180 from being damaged. In some embodiments, the distance H1 may be greater than 1.1 times the distance H2, but is not limited thereto. In the present embodiment, a thickness of the connection pattern 180 is, for example, 1 μm to 50 μm (1 μm≤thickness≤50 μm), but is not limited thereto. A material of the connection pattern 180 may include metals such as silver, gold, copper, etc., and the material may be presented in a slurry state, or presented as metal wires formed on a film, or a colloidal resin mixed with nanoparticles containing at least one of these metals, but not limited thereto.

In the present embodiment, after the connection pattern 180 is formed, an insulation layer 183 may be formed outside the connection pattern 180. To be more specific, the insulation layer 183 may cover the surface of the connection pattern 180 (e.g., the upper surface 181 and the lower surface 182). The insulation layer 183 may be a single-layered or multi-layered structure, and may include, for example, organic materials, inorganic materials, or a combination of the above, but is not limited thereto. The organic material may be, for example, perfluoroalkoxy alkanes (PFA) or resin. The inorganic material may be, for example, silicon oxide or silicon nitride.

The insulation layer 183 has an upper surface 184 on the upper surface 181 of the connection pattern 180 and a lower surface 185 on the lower surface 182 of the connection pattern 180. There is a distance H3 measured along the direction Y between the first surface 111 of the substrate 110 and the topmost point of the insulation layer 183. In the present embodiment, the distance H1 may be greater than the distance H3. In some embodiments, the distance H1 may be greater than 1.1 times the distance H3, but is not limited thereto.

In the step S10, a third circuit test process is performed. Specifically, a predetermined voltage is applied to the second circuit 160 to test whether abnormal circuit issues happen in the electrical connection from the second circuit 160 to the first circuit 120 via the connection pattern 180. For example, at least a portion of the third bonding pads 162 may be exposed by the above mentioned additional patterning process or the second cutting lanes 173 and 174 with greater widths, and the predetermined voltage is applied to the exposed third bonding pads 162 of the second circuit 160 by contacting with probe(s) 140. A test result is obtained to determine whether the open circuit, short circuit, or other abnormal circuit issues happen in the electrical connection from the second circuit 160 to the first circuit 120 via the connection pattern 180.

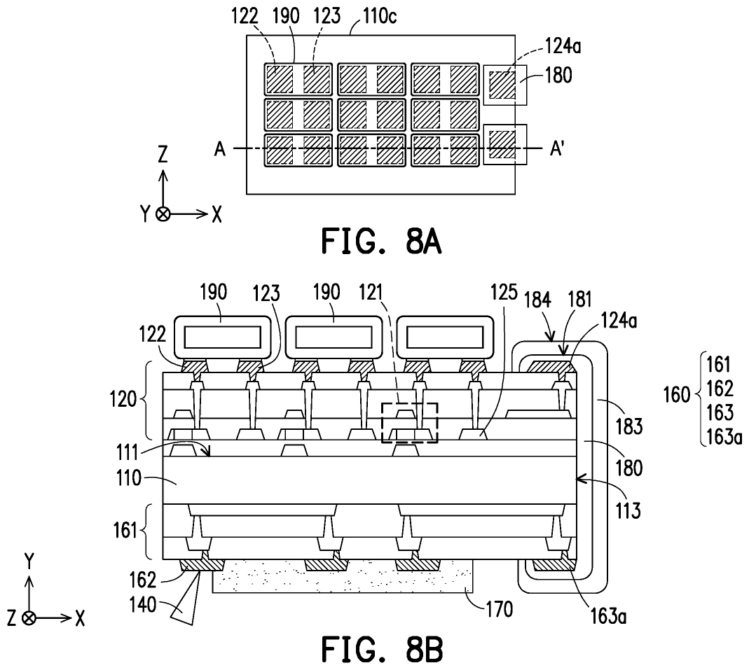

Referring to FIG. 1, FIG. 8A, and FIG. 8B simultaneously, the steps S11 and S12 are sequentially performed. In the step S11, the first protection layer 150 is removed, and a plurality of light emitting elements 190 are transferred onto the first surface 111 of the substrate 110 to electrically connect the first circuit 120 to form a panel. Specifically, all or part of the first protection layer 150 may be removed to expose the first bonding pads 122 and the second bonding pads 123. Next, after removing the first protection layer 150 and exposing the first bonding pads 122 and the second bonding pads 123, the light emitting elements 190 are transferred and bonded to the first bonding pads 122 and the second bonding pads 123 of the first circuit 120, and each of the light-emitting elements 190 is electrically connected to the corresponding transistors 121 and the corresponding first signal wires 125. It should be noted that in the present disclosure, a panel is formed by including the light emitting elements 190 and the previously built structure which may include the substrate 110, the first circuit 120, the second circuit 160, and the connection pattern 180. In other aspect, the border between the active region AR and the peripheral region PR can be defined as the line connection of the outmost endpoints of the light emitting regions of all the outmost light emitting elements. For example, if there is a rectangular light emitting element array in a panel, the line connection of the topmost endpoints of the light emitting regions of the topmost row of light emitting elements, the bottommost endpoints of the light emitting regions of the bottommost row of light emitting elements, the leftmost endpoints of the light emitting regions of the leftmost column of light emitting elements, the rightmost endpoints of the light emitting regions of the rightmost column of light emitting elements can be together to define the border between the active region AR and the peripheral region PR.

It should be noted that it is only an example to use flip-chip type LEDs as the light emitting elements 190 in the present embodiment, but it is not limited thereto. There are various types of light emitting elements 190, and there are various methods to form an electrical connection between one of the light emitting elements 190 and at least one of the first bonding pads 122 and the second bonding pads 123.

In the step S12, a fourth circuit test process is performed. Specifically, a predetermined voltage is applied to the second circuit 160 to test whether abnormal circuit issues happen in the electrical connection from the second circuit 160 to the light-emitting elements 190 via the connection pattern 180 and the first circuit 120. For example, the predetermined voltage is applied to the exposed third bonding pads 162 of the second circuit 160 by contacting with probe(s) 140. A test result is obtained to determine whether the open circuit, short circuit, or other abnormal circuit issues happen in the electrical connection from the second circuit 160 to the light-emitting elements 190 via the connection pattern 180 and the first circuit 120.

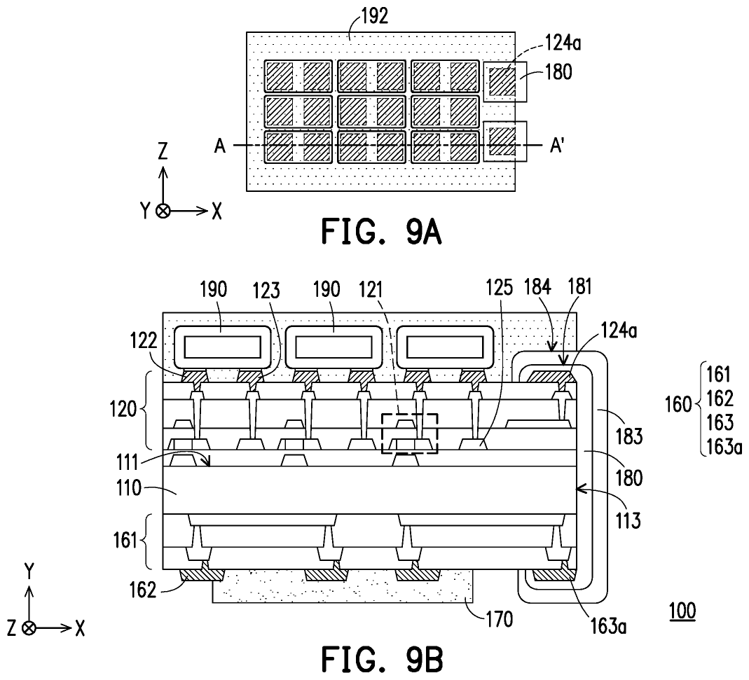

Referring to FIG. 1, FIG. 9A, and FIG. 9B simultaneously, the step S13 is performed. In the step S13, a packaging process is performed. Specifically, a molding compound 192 may be formed on the first surface 111 of the substrate 110 to encapsulate the light-emitting elements 190, the first bonding pads 122, the second bonding pads 123 and the upper surface 184 of the insulation layer 183.

Finally, referring to FIG. 1, the step S14 is performed. In the step S14, the second protection layer 170 is removed, and at least one integrated circuit (IC) (not shown) is bonded onto the second surface 112 of the substrate 110 to electrically connect the second circuit 160 to manufacture an electronic device. Specifically, after removing the second protection layer 170 and exposing the third bonding pads 162 which are not exposed in the previous steps, the at least one integrated circuit is bonded to the third bonding pads 162 of the second circuit 160 to electrically connect to the corresponding third bonding pads 162 of the second circuit 160. It should be noted that in the present disclosure, an electronic device may be defined to include at least a panel which is formed in the above mentioned steps S1 to S13, and at least one integrated circuit bonded onto the panel. In the present embodiment, although the method of manufacturing the electronic device 100 starts with the substrate 110 and then the substrate 110 is cut it into several pieces after forming the second protection layer 170, but is not limited to thereto. In some embodiments, the method of manufacturing the electronic device 100 may be performed without cutting. That is, the electronic device can be manufactured according to the steps S1-S7 and the steps S9-S14, and the step S8 is omitted.

In the method of manufacturing the electronic device 100 of the present embodiment, although the protection layers (e.g., the first protection layer 150 and the second protection layer 170) are respectively formed on the first surface 111 and the second surface 112 of the substrate 110, but is not limited thereto. In some embodiments, the protection layer may also be formed only on the first surface 111 or the second surface 112 of the substrate 110, that is, only one protection layer (e.g., the first protection layer 150 or the second protection layer 170) may be formed.

In short, in the method of manufacturing the electronic device of the present embodiment, by forming the first protection layer 150 on the first circuit 120 and/or the second protection layer 170 on the second circuit 160, the first circuit 120 and/or the second circuit 160 may be protected from damage during manufacturing the electronic device 100. By disposing the connection pattern 180 on the side surface 113 of the substrate 110 and extending the connection pattern 180 to electrically connect with at least one of the first conductive pad 124a and at least one of the second conductive pad 163a, the first circuit 120 disposed on the first surface 111 of the substrate 110 may be electrically connected to the second circuit 160 disposed on the second surface 112 of the substrate 110. By forming an insulation layer 183 on the connection pattern 180, the connection pattern 180 may be protected from damage during manufacturing the electronic device 100. Therefore, the method of manufacturing the electronic device of the present embodiment may have the effect of improving yield or increasing process convenience.

Other embodiments will be listed below for illustration. It must be noted that, the following embodiments use the component numbers and parts of the foregoing embodiments, in which the same reference numerals are used to indicate the same or similar components, and the description of the same technical content is omitted. For the description of the omitted parts, reference may be made to the foregoing embodiments, and the following embodiments are not repeated.

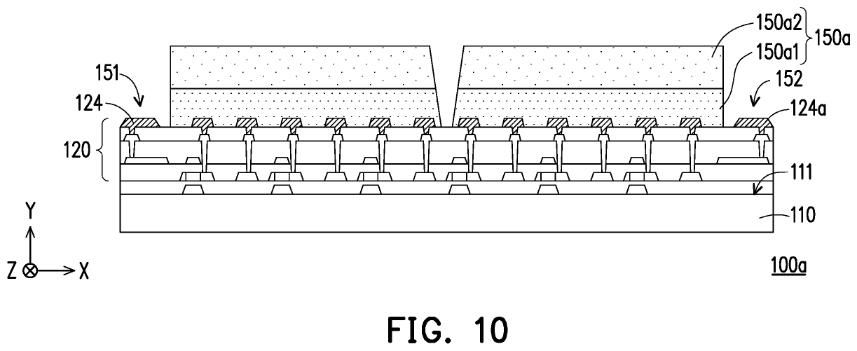

FIG. 10 is a schematic cross-sectional view of a structure according to another embodiment of the disclosure. Please refer to FIG. 3B and FIG. 10 at the same time, the structure 100a in the present embodiment is similar to the structure in FIG. 3B. The structure 100a of the present embodiment is different from the structure in FIG. 3B mainly in that: a first protection layer 150a of the structure 100a is a two-layered structure.

Specifically, the first protection layer 150a may include a first layer 150a1 and a second layer 150a2. The first layer 150a1 is disposed on the first circuit 120, and the second layer 150a2 is disposed on the first layer 150a1. In the present embodiment, the second layer 150a2 may be denser (e.g., higher density) than the first layer 150a1, and the first protection layer 150a can be separated later.

FIG. 11 is a schematic top view of a structure according to another embodiment of the disclosure. Please refer to FIG. 3A and FIG. 11 at the same time, a structure 100b in the present embodiment is similar to the structure in FIG. 3A. The structure 100b of the present embodiment is different from the structure in FIG. 3A mainly in that: first openings 151b and 152b adjacent to a first protection layer 150b of the structure 100b are via holes.

Specifically, one of the first openings 151b may correspond to one of the first conductive pads 124, and one of the first opening 152b may correspond to one of the first conductive pads 124a, but not limited thereto, in other embodiments, one first opening 151b (or one first opening 152b) may correspond to more than one first conductive pad.

One of the first opening 151b (or the first opening 152b) overlaps one corresponding first conductive pad 124 (or the first conductive pad 124a) in the normal direction (direction Y) of the substrate 110. An area A3 of one of the first openings 151b (or the first openings 152b) may be greater than an area A4 of the corresponding first conductive pad 124 (or the first conductive pad 124a), and the area A3 may be less than an area of the region 110c. In the present embodiments, the area A3 of one of first openings 151b (or the first openings 152b) may be greater than 1.3 times the area A4 of the corresponding first conductive pad 124 (or the first conductive pad 124a), but is not limited thereto.

FIG. 12 is a schematic top view of a structure according to another embodiment of the disclosure. Please refer to FIG. 11 and FIG. 12 at the same time, a structure 100c in FIG. 12 is similar to the structure 100b in FIG. 11. The structure 100c of the present embodiment is different from the structure 100b mainly in that: the structure 100c further includes a plurality of first conductive pads 124b, 124c, and 124d and a plurality of first openings 151c, 151d, and 151e.

Specifically, in the normal direction (direction Y) of the substrate 110, the first openings 151c overlap and expose the first conductive pads 124b, the first openings 151b overlap and expose the first conductive pads 124, the first openings 152b overlap and expose the first conductive pads 124a, the first openings 151d overlap and expose the first conductive pads 124c, and the first openings 151e overlap and expose the first conductive pads 124d. In addition, the first conductive pads 124b and the first openings 151c are located corresponding to the edge 116 and the edge 117 of the substrate 110. The first conductive pads 124 and the first openings 151b are located corresponding to the edge 114 of the substrate 110. The first conductive pads 124a and the first openings 152b are located corresponding to the edge 115 of the substrate 110. The first conductive pads 124c and the first openings 151d are located corresponding to the edges 1531 and 1532 of the first cutting lane 153. The first conductive pads 124d and the first openings 151e are located corresponding to the edges 1541 and 1542 of the first cutting lane 154.

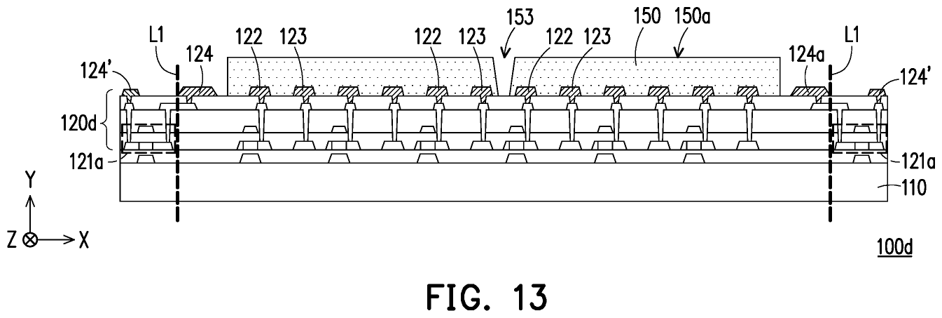

FIG. 13 is a schematic cross-sectional view of a structure according to another embodiment of the disclosure. Please refer to FIG. 3B and FIG. 13 at the same time, a structure 100d in the present embodiment is similar to the structure in FIG. 3B. The structure 100d of the present embodiment is different from the structure in FIG. 3B mainly in that: the first circuit 120d of the structure 100d further includes a plurality of test pads 124′ and a plurality of switching elements 121a.

In the present embodiment, the plurality of test pads 124′ and the plurality of switching elements 121a are disposed on a periphery of the first conductive pads 124 and 124a, and the first conductive pads 124 and 124a are located between the test pads 124′ and the first bonding pads 122. The plurality of switching elements 121a may be regarded as transistors, but is not limited thereto. The plurality of switching elements 121a are electrically connected to the plurality of test pads 124′ and the plurality of first conductive pads 124 and 124a. In the present embodiment, since the first circuit 120 is complicated, a design of the test pads 124′ and the switching elements 121a may be useful to simplify the subsequent circuit test process(es) (such as the first circuit test process, but is not limited thereto). After the first circuit test process is completed or the second circuit 160 is formed, the cutting tool may be used to remove the plurality of test pads 124′ and the plurality of switching elements 121a along cutting lines Ll.

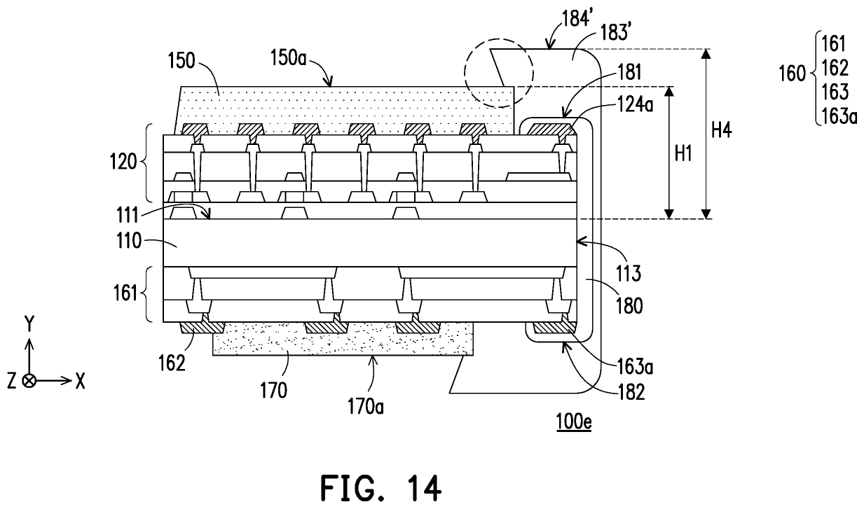

FIG. 14 is a schematic cross-sectional view of a structure according to another embodiment of the disclosure. Please refer to FIG. 7B and FIG. 14 at the same time, a structure 100e in the present embodiment is similar to the structure in FIG. 7B. The structure 100e of the present embodiment is different from the structure in FIG. 7B mainly in that: an insulation layer 183′ of the structure 100e covers a portion of the first protection layer 150 and/or a portion of the second protection layer 170.

Specifically, the insulation layer 183′ covers the top surface 150a of the first protection layer 150 and/or a surface 170a of the second protection layer 170 away from the second circuit 160. In the present embodiment, along the Y-direction, The distance H1 between the first surface 111 of the substrate 110 and the top surface 150a of the first protection layer 150 may be less than the distance H4 between the first surface 111 of the substrate 110 and the topmost point of the insulation layer 183′, and a protection effect provided by the insulation layer 183′ may be ensured. In the present embodiment, the insulation layer 183′ has an inverted taper (as shown in a dashed circle) and the inverted taper is disposed on a portion of the first protection layer 150 (or the second protection layer 170), and the first protection layer 150 (or the second protection layer 170) may be easily detached in the subsequent manufacturing process.

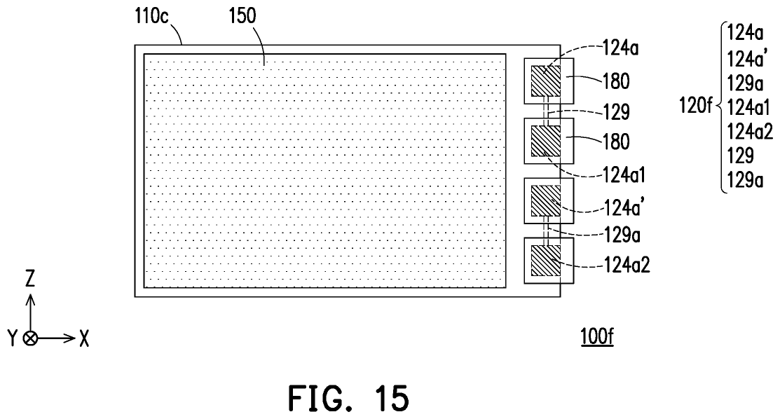

FIG. 15 is a schematic top view of a structure according to another embodiment of the disclosure. Please refer to FIG. 7A and FIG. 15 at the same time, a structure 100f in the present embodiment is similar to the structure in FIG. 7A. The structure 100f of the present embodiment is different from the structure in FIG. 7A mainly in that: the first circuit 120f of the structure 100f further includes redundant first conductive pads 124a1 and 124a2 and wires 129 and 129a.

Specifically, the wire 129 may be electrically connected to the first conductive pad 124a and the redundant first conductive pad 124a1, and the wire 129a may be electrically connected to the first conductive pad 124a′ and the redundant first conductive pad 124a2. The first conductive pad 124a, the redundant first conductive pad 124a1, the first conductive pad 124a′ and the redundant first conductive pad 124a2 are respectively electrically connected to the corresponding connection pattern 180. Therefore, when the first conductive pad 124a (or the first conductive pad 124a′) is damaged, the redundant first conductive pad 124a1 (or the redundant first conductive pad 124a2) may be used to replace the damaged first conductive pad 124a (or the first conductive pad 124a′) to transmit signals.

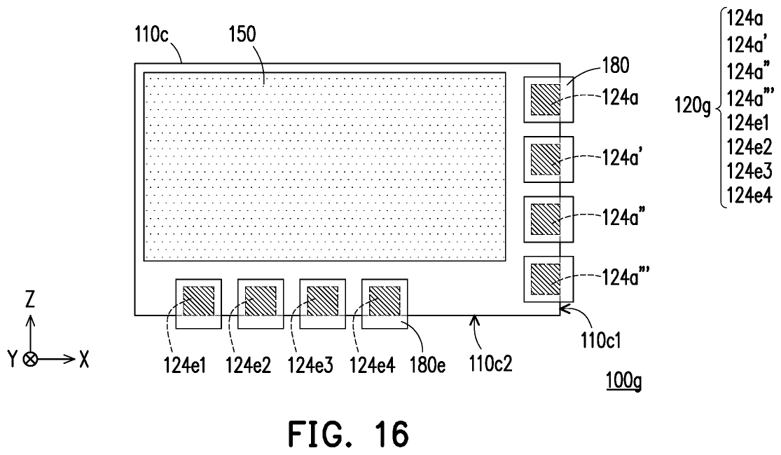

FIG. 16 is a schematic top view of a structure according to another embodiment of the disclosure. Please refer to FIG. 7A and FIG. 16 at the same time, a structure 100g in the present embodiment is similar to the structure in FIG. 7A. The structure 100g of the present embodiment is different from the structure in FIG. 7A mainly in that: the first circuit 120g of the structure 100g further includes first conductive pads 124a′, 124a″, and 124a′″ and redundant first conductive pads 124e1, 124e2, 124e3, and 124e4.

In the present embodiment, the first conductive pads 124a, 124a′, 124a″, and 124a′″ are disposed on an edge 110c1 of the region 110c, and the redundant first conductive pads 124e1, 124e2, 124e3, and 124e4 are disposed on an edge 110c2 of the region 110c. The edge 110c1 may be adjacent to the edge 110c2, but is not limited thereto. The first conductive pad 124a (or the first conductive pad 124a′, 124a″, or 124a′″) is electrically connected to the redundant first conductive pad 124e1 (or the redundant first conductive pad 124e2, 124e3, or 124e4), and the first conductive pad 124a (or the first conductive pad 124a′, 124a″, or 124a′″) and the redundant first conductive pad 124e1 (or the redundant first conductive pad 124e2, 124e3, or 124e4) are electrically connected to the same signal. The first conductive pad 124a, the first conductive pad 124a′, the first conductive pad 124a″ and the first conductive pad 124a″ are respectively electrically connected to the corresponding connection patterns 180. The redundant first conductive pad 124e1, the redundant first conductive pad 124e2, the redundant first conductive pad 124e3 and the redundant first conductive pad 124e4 are respectively electrically connected to the corresponding connection patterns 180e. Therefore, when the first conductive pad 124a (or the first conductive pad 124a′, 124a″, or 124a′″) is damaged, the redundant first conductive pad 124e1 (or the redundant first conductive pad 124e2, 124e3, or 124e4) may be used to replace the damaged first conductive pad 124a (or the first conductive pad 124a′, 124a″, or 124a′″) to transmit signals.

In summary, in the method of manufacturing the electronic device of the present embodiment, by forming the first protection layer on the first circuit and/or the second protection layer on the second circuit, the first circuit and/or the second circuit may be protected from damage during manufacturing the electronic device. By disposing the connection pattern on the side surface of the substrate, the first circuit disposed on the first surface of the substrate may be electrically connected to the second circuit disposed on the second surface of the substrate. By forming an insulation layer on the connection pattern, the connection pattern may be protected from damage during manufacturing the electronic device. Therefore, the method of manufacturing the electronic device of the present embodiment may have the effect of improving yield or increasing process convenience.

It will be apparent to those skilled in the art that various modifications, combinations, and variations can be made to the disclosed embodiments without departing from the scope or spirit of the disclosure. In view of the foregoing, it is intended that the disclosure covers modifications and variations provided that they fall within the scope of the following claims and their equivalents.

What is claimed is:

1. A method of manufacturing an electronic device, comprising:
providing a substrate having a first surface, a second surface opposite to the first surface, and a side surface between the first surface and the second surface;
forming a first circuit on the first surface, wherein the first circuit comprises a transistor, a plurality of pads which comprises a first bonding pad, a second bonding pad, a first conductive pad and a first passivation layer, wherein the first passivation layer is disposed on the transistor, and the first bonding pad, the second bonding pad and the first conductive pad are respectively disposed on the first passivation layer;
forming a first protection layer on one of the first surface and the second surface; and
forming a first cutting lane on the substrate.

2. The method of manufacturing an electronic device as claimed in claim 1, further comprising:
cutting the substrate along the first cutting lane after forming the first cutting lane.

3. The method of manufacturing an electronic device as claimed in claim 1, further comprising:
testing the first circuit by applying a predetermined voltage to one of the plurality of pads of the first circuit.

4. The method of manufacturing an electronic device as claimed in claim 3, wherein the testing is performed after forming the first circuit and before forming the first protection layer.

5. The method of manufacturing an electronic device as claimed in claim 1, further comprising:
forming a second circuit on the second surface;
forming a second protection layer on another one of the first surface and the second surface; and
forming a second cutting lane on the substrate, wherein the first cutting lane overlaps the second cutting lane in a normal direction of the substrate.

6. The method of manufacturing an electronic device as claimed in claim 5, wherein the first cutting lane and the second cutting lane are different in width.

7. The method of manufacturing an electronic device as claimed in claim 5, further comprising:
making the second circuit electrically connected with the first conductive pad of the first circuit by forming a connection pattern overlapping the side surface, a portion of the first circuit and a portion of the second circuit after forming the second circuit.

8. The method of manufacturing an electronic device as claimed in claim 7, further comprising:
testing an electrical connection between the first circuit and the second circuit by applying a predetermined voltage to one of a plurality of pads of the second circuit after forming the connection pattern.

9. The method of manufacturing an electronic device as claimed in claim 5, further comprising:
cutting the substrate along the first cutting lane or the second cutting lane after forming the second cutting lane.

10. The method of manufacturing an electronic device as claimed in claim 7, wherein the first protection layer is disposed on the first surface of the substrate, a maximum distance between the first surface of the substrate and a top surface of the first protection layer is greater than a maximum distance between the first surface of the substrate and a topmost point of the connection pattern in the normal direction of the substrate.

11. The method of manufacturing an electronic device as claimed in claim 7, further comprising:
forming an insulation layer on the connection pattern after forming the connection pattern.

12. The method of manufacturing an electronic device as claimed in claim 11, wherein the first protection layer is disposed on the first surface of the substrate, a maximum distance between the first surface of the substrate and the top surface of the first protection layer is greater than a distance between the first surface of the substrate and the topmost point of the insulation layer in the normal direction of the substrate.

13. The method of manufacturing an electronic device as claimed in claim 5, further comprising:
testing the second circuit by applying a predetermined voltage to one of a plurality of pads of the second circuit.

14. The method of manufacturing an electronic device as claimed in claim 13, wherein the testing is performed after forming the second circuit and before forming the second protection layer.

15. The method of manufacturing an electronic device as claimed in claim 7, wherein the first protection layer is disposed on the first surface of the substrate, and the method further comprises:
removing the first protection layer to expose a first bonding pad and a second bonding pad; and
transferring and bonding a light emitting element to the first bonding pad and the second bonding pad.

16. The method of manufacturing an electronic device as claimed in claim 15, further comprising:
testing the electrical connection between the light emitting element and the second circuit by applying a predetermined voltage to one of a plurality of pads of the second circuit after bonding the light emitting element.

17. The method of manufacturing an electronic device as claimed in claim 1, wherein the transistor comprises a source electrode and a drain electrode, and the first conductive pad is disposed on the source electrode and the drain electrode.

18. The method of manufacturing an electronic device as claimed in claim 1, wherein the first bonding pad, the second bonding pad and the first conductive pad are disposed on the same layer.
